(19) United States
(12) Patent Application Publication
(10) Pub. No.: US 2024/0014331 A1
(43) Pub. Date: Jan. 11, 2024

(54) PHOTOVOLTAIC DEVICES

(71) Applicant: EXASUN B.V., The Hague (NL)

(72) Inventors: Michiel Herman MENSINK, The Hague (NL); Jan-Jaap Eduard VAN OS, The Hague (NL)

(73) Assignee: EXASUN B.V., The Hague (NL)

(21) Appl. No.: 18/035,813

(22) PCT Filed: Nov. 9, 2021
(86) PCT No.: PCT/NL2021/050688

§ 371 Date: May 8, 2023

(30) Foreign Application Priority Data
Nov. 9, 2020 (NL) 2026856

(51) Int. Cl. H01L 31/0216; H01L 31/0236; H01L 31/048; H01L 31/18; H01L 31/0475

(52) U.S. Cl. CPC H01L 31/02168; H01L 31/02366; H01L 31/0488; H01L 31/186; H01L 31/0475

(57) ABSTRACT

The present invention relates to a photovoltaic element comprising: •i. a light transmissive, coloured multilayer top sheet having an appearance that exhibits a colouration change depending on the viewing angle, the top sheet comprising: •a. a textured transparent front cover sheet (2), and •b. a pigmented top coating layer (3) disposed on the backside of the top sheet with respect to the direction of the incandescent light; •ii. a first encapsulant layer (4); •iii. one or more photovoltaic cells (5), each comprising at least one photovoltaically active surface, and comprising two electrically-conductive electrode layers with a photovoltaic material disposed between them; •iv. a second encapsulant layer (6), and •v. a back cover sheet (7).

### FIELD OF THE INVENTION

The present invention relates generally to photovoltaic (PV) devices. The present invention relates more particularly to photovoltaic devices for architectural use, such as in building integrated-photovoltaic systems, and more specifically to photovoltaic claddings, e.g. for facades, roofs and noise barriers, and methods of manufacturing photovoltaic architectural elements.

### BACKGROUND OF THE INVENTION

Existing photovoltaic modules do not blend well aesthetically with conventional roofing materials. Photovoltaic materials tend to have a deep blue or black colour, which lends them increased solar absorptivity and therefore increased efficiency. Standard roof tiles, for example, are generally grey, black, green or brown in tone. Moreover, many synthetic roofing materials, such as polymeric tiles, slates and panels are fabricated to appear like a more traditional materials, in particular ceramic. Accordingly, the contrast between photovoltaic materials and standard roofing materials can be quite dramatic.

Also, unlike conventional rooftop solar where full-sized solar panels are installed with mounting hardware over an existing roof surface, in architectural PV systems the power generating elements are built into roof surface components. For example, roofing tiles that contain photovoltaic elements may be integrated with standard roof tiles to create a uniform aesthetic while allowing customers to enjoy the same financial and environmental benefits of generating their own solar energy that conventional solar owners enjoy.

A challenge of architectural PV systems is achieving visual uniformity. In various prior art architectural PV systems, the active solar roof portions are so visibly distinct from other materials that it is easy to tell which tiles contain PV cells, and which do not. This creates a non-uniform aesthetic with stark contrast between active and non-active sections of the clad portion of a building.

This problem of visual mismatch, however, is not limited to architectural PV systems. Even within a single roof tile, the solar cells or active solar regions are clearly distinguishable from the other surrounding materials. This is due in part to edge setback constraints that impose a fixed, non-active edge border around active solar portions of solar roof tiles or architectural PV modules. Therefore, there exists a need for an architectural PV system and module that ameliorates deficiencies of prior art architectural PV systems.

Yet further, solutions that employ for instance homogeneously coloured glass top sheets are usually not very high in efficiency. A slightly different approach concerns the use of homogenous optical filters in the topsheet, which eliminate entire radiation bands, as for instance is disclosed U52008/0006323, or U52019/0097571. While these filters may obscure the inner photovoltaic structures positioned between the front and back covers, by blocking and filtering out visual light reflections, the use of such filter reduces the efficacy of the photovoltaic cells; and only allows to attain very dark solar roof tiles. Accordingly, there remains a need for colour adjusted PV modules with higher efficiency.

### SUMMARY OF THE INVENTION

In a first aspect the present invention relates to a photovoltaic element comprising:
i. a light transmissive, coloured birefringent multilayer top sheet having an appearance that exhibits a colouration change depending on the viewing angle, the top sheet comprising:
a. a textured transparent front cover sheet, and
b. a pigmented top coating layer disposed on the backside of the top sheet with respect to the direction of the incandescent light;
ii a first encapsulant layer;
iii. one or more photovoltaic cells, each comprising at least one photovoltaically active surface, and comprising two electrically-conductive electrode layers with a photovoltaic material disposed between them;
iv. a second encapsulant layer, and
v. a back cover sheet.

In a second aspect, it relates to a method of preparing a photovoltaic element according to any one of the preceding claims, comprising: a) coating a textured transparent front cover sheet with a pigmented coating composition in suitable thickness, and b) subjecting the coated top sheet to a curing process, to obtain the textured birefringent multilayer top sheet having an appearance that exhibits a colouration change depending on the viewing angle, and optionally wherein the coating process is wet coating process, and wherein the curing process is a radiation curing process.

In a further aspect the present invention relates to a method c) providing a stack comprising the birefringent multilayer top sheet having an appearance that exhibits a colouration change depending on the viewing angle; a first encapsulant material; one or more photovoltaic cells comprising at least one photovoltaically active surface and comprising two electrically-conductive electrode layers with a photovoltaic material disposed between them; a second encapsulant material, and ii.) subjecting the stack obtained in i.) to a suitable pressure and temperature, to obtain a photovoltaic element.

In a further aspect the present invention relates to a photovoltaic element comprising a plurality of photovoltaic elements, for disposition on a structure.

The photovoltaic architectural PV elements of the present invention can result in a number of advantages over prior art methods. For example, the photovoltaic architectural PV elements of the present invention can have enhanced aesthetic matching between the appearance of the building substrate and an encapsulated photovoltaic element disposed thereon. Moreover, the photovoltaic elements of some embodiments of the present invention can be constructed so that their entire visible surface matches the appearance of the photovoltaic cells.

The accompanying drawings are not necessarily to scale, and sizes of various elements can be distorted for clarity.

### BRIEF DESCRIPTION OF THE DRAWING

FIG. 1 is a schematic side cross-sectional view and a schematic top view of an encapsulated photovoltaic element including the coloured layer and the patterned top sheet.

### DETAILED DESCRIPTION OF THE INVENTION

Unless stated otherwise, all percentages, parts, ratios, etc., are by weight. When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. The transitional phrase “consisting essentially of limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to produce them or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers (i.e. copolymerized units of those monomers) or that amount of the monomers, and the corresponding polymers and compositions thereof.

In describing and/or claiming this invention, the term “copolymer” is used to refer to polymers formed by copolymerization of two or more monomers. Such copolymers include dipolymers, terpolymers or higher order copolymers.

Typical photovoltaic elements according to the invention preferably have a layer sequence as follows: a top sheet comprising a textured front sheet and a pigmented layer adjacent and adhered thereto, an encapsulant polymer layer, a photovoltaic cell, an encapsulant layer and a back sheet.

The term “first layer” and “second layer” refers to any layer of the module that is present in the direction of the incandescent light. The layer may be the layer that is directly in contact with the glass or front sheet, as the pigmented coating layer, or may be an intermediate layer. In this respect, the next layer refers to a layer further down in the direction of the incandescent light. The layers may be directly adjacent to each other, or may be separated by further intermediate layers.

Top Sheet

The encapsulated photovoltaic element includes a top layer material at its top surface, i.e. facing the direction of the incandescent light, and a bottom or backing layer material at its bottom surface. The top layer is comprised of a textured top sheet, with the texture pointing inwardly, and pigmented coating layer adhered to the textured side of the top sheet.

The top layer material may, for example, provide environmental protection to the underlying photovoltaic cells, and any other underlying layers. Examples of suitable materials for the top layer material include any suitable transparent material, e.g. polymeric materials, in particular epoxy, (meth)acrylate or polycarbonate materials, or fluoropolymers, for example ETFE, PFE, FEP, PCTFE or PVDF.

The top layer material can alternatively be, for example, be a glass or ceramic sheet. Thin hardened and highly transmissive glass or glass ceramic sheets are particularly preferred. Such glass sheets advantageously are provided with a micro-texture at one side, which can then be coated with the pigmented layer.

The top sheet may further include at least one antireflection coating, for example as the top layer material, or disposed between the top layer material and the photovoltaic cells.

Preferably the top sheet, facing the incoming radiation has a thickness of between 1.5 and 4 mm. Preferred are glass sheets, which may for example be float glass or roll glass having a texture structure applied at least to one side of the sheet. The glass sheet may optionally be thermally treated. The glass sheet may comprise sodium free glass, for example alumina silicate or borosilicate glass. For large volume production it is preferred to use a soda lime glass or borosilicate glass. The soda lime glass may comprise between 67-75% by weight SiO₂, between 10-20% by weight; Na₂O, between 5-15% by weight CaO, between 0-7% by weight MgO, between 0-5% by weight Al₂O₃; between 0-5% by weight K₂O, between 0-1.5% by weight Li₂O and between 0-1%, by weight BaO. Such a glass will suitably have a transparency of higher than 90%. Suitably the glass has been subjected to a thermally toughening treatment after the texture has been applied.

The surface of the glass layer, especially the surface not facing the pigmented coating layer and facing the incoming radiation may be preferably coated with a suitable anti-reflection layer. The anti-reflective layer will limit the radiation which reflects at the glass surface. Limiting this reflection will increase the radiation passing the glass element which will as a result enhance the efficiency of the glass element to transmit radiation. Preferably the coating is applied to one glass layer, namely the glass layer which will in use face the incoming radiation, i.e. sunlight. A suitable anti-reflection coating will comprise of a layer of porous silica. The porous silica may be applied by a sol-gel process as for example described in U.S. Pat. No. 7,767,253. The porous silica may comprise of solid silica particles present in a silica-based binder. Processes to prepare glass layers having an anti-reflective coating are for example described in WO-A-2004104113 and WO-A-2010100285.

The side facing the pigmented coating layer is provided with a micro-texture. The actual geometry of the texture is not important, as long as it allowed the top sheet when coated to give the desired birefringent colour appearance. Typical textures comprise dimples, pyramidal structures, grids and the like, such as for instance disclosed in EP-A-1774372 or EP-A-2850664.

The concentration of the pigments in the top sheet pigmented layer will depend on the chosen colour effect of the module. Some pigments or pigment combinations are more effective and will require a lower concentration in the layer and some compounds will require a higher concentration because they are less efficient in the desired colour tone.

The encapsulated photovoltaic element may comprise other layers interspersed between the top layer material and the bottom layer material. For example, the encapsulated photovoltaic element can include structural elements, such as a reinforcing layer of glass, metal or polymer fibres, or a rigid film; adhesive and encapsulant layers, such as EVA to adhere other layers together; mounting structures, such as clips, holes, or tabs; and one or more optionally connectorized electrical cables for electrically interconnecting the photovoltaic cell(s) of the encapsulated photovoltaic element with an electrical system.

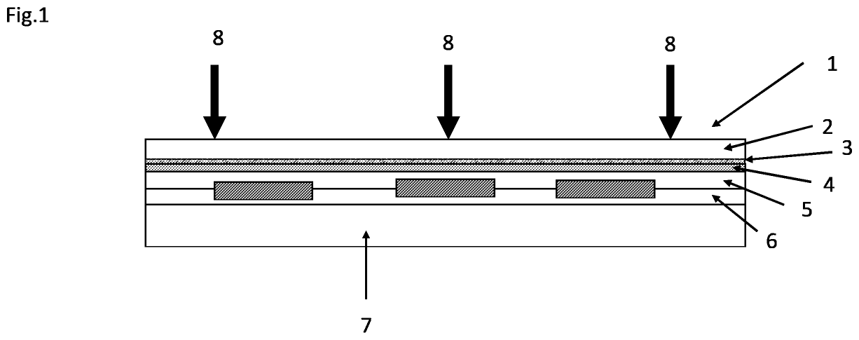

An example of an encapsulated photovoltaic element suitable for use in the present invention is shown in schematic side cross-sectional view in FIG. 1.

In one embodiment (1) as shown in FIG. 1, a top sheet (2) glass with a textured layer (3) obtained by a float and texturing process was cut into sheets. The glass sheets thus obtained were cleaned in a standard industrial process, and coated by a screen printing and UV curing process with a pigmented layer (3).

The thus formed coloured top sheet was then employed in a conventional process, namely a first, transparent encapsulant foil (4); a PV cell grid with leads (5), a pigmented back encapsulant foil layer (6) which mimics the colour of the photovoltaic cells and a float glass back sheet layer (7) where stacked in a mold, and subjected to reduced pressure and heating so that the encapsulant layers could flow out and crosslink, thus forming a PV module according to the subject invention. The direction of the incoming light is given as (8).

Depending on the embodiment, module or solar cell, an integrated series connection was achieved via various intermediate structuring steps or a front grid applied by screen printing.

Manufacturing Process

The top sheets according to the invention can be advantageously prepared by method of preparing a photovoltaic element according to any one of the preceding claims, comprising: a) coating a textured transparent front cover sheet with a pigmented coating composition in suitable thickness, and b) subjecting the coated top sheet to a curing process, to obtain the textured coloured light transmissive front cover sheet.

Prefearbly, the coating process is wet coating process, and wherein the curing process is a radiation curing process, e.g. a screen-printing process followed by a UV curing step. Using a modern printing equipment, this permits manufacture of different patterns and colours on the same production line, with minimal loss of time.

Lamination

A PV module or element according to the invention may be prepared by stacking the different layers of the top sheet and the photovoltaic cell, additional encapsulant layer or layers and a backsheet layer and subjecting the formed stack to a lamination process step.

Prefearbly, the method further comprises c) providing a stack comprising the light transmissive coloured top sheet obtained; a first encapsulant material; one or more photovoltaic cells comprising at least one photovoltaically active surface and comprising two electrically-conductive electrode layers with a photovoltaic material disposed between them; a second encapsulant material, and ii.) subjecting the stack obtained in i.) to a suitable pressure and temperature, to obtain a photovoltaic element.

To carry out encapsulation, a laminating encapsulant film, and a top sheet, for instance a coated glass sheet, for example a low-iron soda-lime glass, are positioned over the PV module having integrated serial connection, and a second encapsulant sheet and a backsheet are laid down and subsequently laminated in a thermal curing step. Typical lamination temperatures are in the range from to 200° C. The lamination temperature may be between 115 and 175° C. and wherein the environment of the stack preferably has a pressure of less than 30 mBar, more preferably less than 1 mBar. In this process the stack is preferably present in a vacuum laminator and pressure bonded under conversion heating at a temperature in the range of from of 115 to 175° C., preferably 140 to 165° C., most preferably from 145 to 155° C. The laminate is preferably also subjected to degassing. The compression lamination pressure preferably is in the range of from of 0.1 to 1.5 kg/cm 2. The lamination time typically is in the range of from 5 to 25 minutes. This heating enables for example the ethylene-vinyl acetate copolymer contained in the polymer sheet according to the invention and in the encapsulant layer to crosslink, whereby the photovoltaic cell, the polymer sheet and the encapsulant layer are strongly adhered to seal the photovoltaic cell and obtain the photovoltaic module according to the invention. Where “dummy” modules are desired with the same appearance the above process is repeated, however omitting the PV cells.

Encapsulated photovoltaic element include a textured top protective layer comprising coating layer; e.g., a coated glass sheet; a first encapsulant layer, preferably comprising EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells; a optionally pigmented back encapsulant layer; and a backing sheet layer, such as glass, aluminium, PVDF, PVF, PET.

The present invention can be practiced using any of a number of types of architectural substrates. For example, in certain embodiments of the invention, the top surface of the roofing substrate is polymeric (e.g., a polymeric material, or a polymeric coating on a metallic material).

In other embodiments of the invention, the back surface of the element may be metallic.

In other embodiments of the invention, the back surface of the element is coated with roofing granules, such as for instance a bituminous material coated with roofing granules. In other embodiments of the invention, the back surface of the roofing substrate is bituminous such as an uncoated bituminous roofing substrate.

The pigmented and thus coloured coating layer is prefearbly designed to resemble a natural material such ceramics or stone, or other manmade materials such as ceramic or concrete, or to blend in with the environment, e.g. when used for noise barrier along roads or highways.

Applicants found that the combination of the textured top sheet and the presence of plate-like pigments results in a birefringent colour effect, at a relatively low adsorption rate. In particular, the top sheet including the coloured coating layer forms a birefringent multilayer optical film having an angularly-dependent appearance. The colour-shift effect of layer can be further modified by adjusting the reflectance or absorbance behaviour of the layers beneath the birefringent optical film.

Pigments

Suitable pigments are so-called effect pigments, which impart particular lustre or particular colour effects to the products pigmented therewith. In general, effect pigments are substrates, for example comprising metals, mica or synthetic flakes of SiO₂, glass or Al₂O₃ which are coated with one or more layers, for example of metals or metal oxides. In particular, metal oxides are frequently used layer materials since they can be applied to the substrates by precipitation and are very substantially chemically inert, such as titanium dioxide. Particularly suitable pigments may comprise pearlescent pigments, nacreous pigments, metal flake pigments or encapsulated metal flake pigments. In particular, light-interference platelet pigments are known to give rise to various optical effects when incorporated in coatings, including opalescence or pearlescence. An example is the deposition of titanium dioxide layers, which may be precipitated onto a substrate. The crystal form of these layers may also be directed, e.g. by doting a tin dioxide layer, and allowing this layer to control a crystallisation of a precipitating titanium dioxide layer into a rutile modification.

Particularly preferred are multilayer interference pigments consisting of a carrier material coated with alternating layers of metal oxides of high and low refractive index, the layer(s) of the metal oxide of low refractive index being optically inactive. Preferably, the carrier material is mica, another phyllosilicate, glass flakes, or platelet-form silicon dioxide. Preferred are also pigments that comprise an additional coating with complex salt pigments, especially cyanoferrate complexes, for example Prussian Blue and Turnbull's Blue. The pigment may also be coated with organic dyes and, in particular, with phthalocyanine or metal phthalocyanine and/or indanthrene dyes. This may be done by preparing a suspension of the pigment in a solution of the dye and then bringing this suspension together with a solvent in which the dye is of low or zero solubility.

The thickness of the interlayers of metal oxides of low refractive index within a metal oxide layer of high refractive index is from 1 to 20 nm, preferably from 2 to 10 nm. Within this range, a metal oxide layer of low refractive index, for example silicon dioxide, is optically inactive.

The thickness of the layers of metal oxides of high refractive index may be between 20 and 350 nm, preferably between 40 and 260 nm. Since the interlayers of low-refractive-index metal oxides greatly increase the mechanical stability of the layers of high-refractive-index metal oxides, it is also possible to prepare thicker layers of adequate stability. In practice, however, layer thicknesses of only up to 260 nm are employed, which in the case of a titanium dioxide-mica pigment would correspond to a 3^{rd} order green aspect.

The inherent colour as well as the interference colour of the interference pigments according to the invention can be varied within a wide range and optimized with a view to the particular application. Thus, for example, the inherent colour can be selectively established by choosing a coloured substrate and/or by using one or more coloured metal oxides as components of the film covering the carrier. The present invention permits to prepare all kinds of colours and appearances, such as green, gold, terracotta, blue, violet, red or orange. just to name a few colours.

The number and thickness of the interlayers is dependent on the total layer thickness of the metal oxide layer of high refractive index. The interlayer is preferably arranged such that the layer thickness of the metal oxide layers of high refractive index corresponds to the optical thickness, or to an integral multiple of this optical thickness, which is necessary for the respective interference colour.

The metal oxide of high refractive index can be an oxide or mixtures of oxides with or without absorbing properties, such as TiO₂, ZrO₂, Fe₂O₃, Fe₃O₄, Cr₂O₃ or ZnO, or a compound of high refractive index such as, for example, iron titanates, iron oxide hydrates and titanium suboxides, or mixtures and/or mixed phases of these compounds with one another or with other metal oxides.

The metal oxide of low refractive index may be selected from SiO₂, Al₂O₃, AlOOH, B₂O₃ or a mixture thereof and can likewise have absorbing or non-absorbing properties. If desired, the oxide layer of low refractive index may include alkali metal oxides and alkaline earth metal oxides as constituents.

Examples of light-interference platelet pigments that can be employed in the pigmented layer of the present invention include light-interference pearlescent pigment based on mica covered with a thin layer of titanium dioxide and/or iron oxide; platelet crystal effect pigment based upon Al₂O₃ platelets coated with metal oxides, multi colour effect pigments based on SiO₂ platelets coated with metal oxides; ultra interference pigments based on TiO₂ and mica; and mirrorized silica pigments. In one embodiment of the invention, a layer having a metallic or light-interference effect is disposed on a layer having a white reflective pigment (e.g., TiO₂ or ZnO₂). This can increase the efficiency of the metallic/light-interference pigments by increasing scattering from the background. In some embodiments, the one or more colorants can themselves have a multilayer structure, such that thin film interference effects give rise to metallic appearance effects or angular metametrism.

Furthermore, it is of course also possible to incorporate small inorganic pigment particles having a particle size of less than 100 nm and in particular 5 to 50 nm into one or, if desired, more of the films. Suitable light-interference platelet pigments may have an equivalent diameter distribution, according to which 90% of the particles are in the range from 2 to 40 μm, preferably from 5 to 40 μm in particular from 3 to 35 μm, very particularly preferably from 5 to 30 μm. In addition to the equivalent diameter distribution, the thickness distribution of the platelets also plays a role. Thus, suitable base substrates preferably have a thickness distribution, according to which 90% of the particles are in the range from 100 to 3500 nm, preferably 200 to 2600 nm, in particular 250 to 2200 nm.

Preferably, the aspect ratio (aspect ratio:diameter/thickness ratio) of the platelets is 5-200, especially 7-150, and most preferably 10-100.

In some embodiments of the invention, the pigmented layer may include one or more additional or alternative pigments, including but not limited to ultramarine blue, ultramarine purple, cobalt chromite blue, cobalt aluminium blue, chrome titanate, nickel titanate, cadmium sulfide yellow, cadmium sulfide yellow, cadmium sulfoselenide orange, and organic pigments such as perylene black, phthalo blue, phthalo green, quinacridone red, diarylide yellow, azo red, and dioxazine purple. Additional pigments may comprise iron oxide pigments, titanium oxide pigments, composite oxide system pigments, titanium oxide-coated mica pigments, iron oxide-coated mica pigments, scaly aluminium pigments, zinc oxide pigments, copper, nickel, cobalt or iron phthalocyanine pigment, non-metallic phthalocyanine pigment, chlorinated phthalocyanine pigment, chlorinated-brominated phthalocyanine pigment, brominated phthalocyanine pigment, anthraquinone, quinacridone system pigment, diketo-pyrrolipyrrole system pigment, perylene system pigment, monoazo system pigment, diazo system pigment, condensed azo system pigment, metal complex system pigment, quinophthalone system pigment, Indanthrene Blue pigment, dioxadene violet pigment, anthraquinone pigment, metal complex pigment, benzimidazolone system pigment, and the like.

The pigments are added to the coating composition that forms the pigmented layer according to the invention after application in a concentration that is generally suitable for the colour depth and effect to be achieved. Preferably, the pigments according to the invention are present in an amount of from. 0.1 to 80% by weight based on the coating composition, preferably of from 1 to 40%, yet more preferably of from 2 to 15% by weight.

In certain embodiments of the invention, the coloured pigmented layer may also include a coloured, infrared-reflective pigment, for example comprising a solid solution including iron oxide; or a near infrared-reflecting composite pigments. Composite pigments are composed of a near-infrared non-absorbing colorant of a chromatic or black colour and a white pigment coated with the near infrared-absorbing colorant. Near-infrared non-absorbing colorants that can be used in the present invention include organic pigments such as organic pigments including azo, anthraquinone, phthalocyanine, perinone/perylene, indigo/thioindigo, dioxazine, quinacridone, isoindolinone, isoindoline, diketopyrrolopyrrole, azomethine, and azomethine-azo functional groups, and include chromium green-black, chromium iron oxide, zinc iron chromite, iron titanium brown spinel, and chrome antimony titanium.

Preferred black organic pigments include organic pigments having azo, azomethine, and perylene functional groups. Coloured, infrared-reflective pigments can be present, for example, at a level in the range of about 0.1% by weight to about 10 percent by weight of the pigmented layer composition. Preferably, such a coating composition forms a layer having sufficient thickness to provide good colour effect, but at sufficient transparency, such as a thickness of from about 5 μm to about 150 μm.

Applicants found that in spite of the relatively high pigmentation, transmission was not significantly reduced. For instance blue or green coloured PV modules only showed a reduction in efficiency sa compared to unpigmented muddles of from 5 to 8%, whereas even for a terracotta pigmentation, an efficiency reduction of only about 20% was found. This compares very favourably to pigmented solid glass front sheets, and to encapsulants with pigments therein. Without wishing to be bound to any particular theory, it is believed that the combination of the interference pigments and the texture at the inside of the top sheet form a birefringent composite sheet, which scatters light to the eye of the beholder in a more prominent way than traditional pigmented top layers, including those having optical filter layers, while at the same time allowing transmission of sufficient light to maintain a high efficiency.

Advantageously, the present PV modules can be prepared in almost any colour tone, allowing for a very wide applicability ranging from the apparition close to traditional roof tiles, to noise barriers, to colour tones that blend in with the environment, e.g. forest or dunes; and colours chosen to enhance architectural features.

Since not all surfaces of a building or other structures need to, or are suitable for providing photovoltaic electricity, the present invention also pertains to panels that are complementary to the elements according to the invention, but entirely or in part void of PV cells. Such panels accordingly comprise a light transmissive, coloured birefringent multilayer top sheet having an appearance that exhibits a colouration change depending on the viewing angle, the sheet comprising a. a textured transparent front cover sheet; and b. a pigmented top coating layer disposed on the inside of the top sheet with respect to the direction of the incandescent light; a first encapsulant layer, a second encapsulant layer, and a back cover sheet. Such “dummy” panels may also be used to cut or shape for suitable roof coverage, e.g. at corners. While the use of standard pigmented “dummy” panels is disclosed for instance in KR2010/0048453, the use of coloured birefringent topsheets in such panels has not been known. Such panels may therefore be used in combination with the solar modules according to the invention, thereby allowing for a visually homogenous roof or facade surface.

In certain embodiments of the invention, the coloured pigmented layer includes at least one colouring material selected from the group consisting of colouring pigments and UV-stabilized dyes. Additionally, conventional pigments may be employed.

Preferably, the top sheet comprises a pigmented layer disposed on the top sheet in the direction opposite to the incandescent light and facing towards the first encapsulant layer. This second layer preferably reflects a small portion of the visible light, but advantageously has an at least 75% overall energy transmittance, but is substantially transparent to near-IR radiation, i.e. ranging from 700-2500 cm⁻¹.

The pigmented coating layer to be applied on one face of the top sheet advantageously comprises a curable or cross-linkable polymer composition binder, pigment(s), and any additive deemed necessary for application, adhesion or stability.

Preferably, a coating is employed which may be deposited with a conventional coating method, e.g. a screen print, an ink jet print or the like. This polymeric composition may preferably comprise transparent and protective UV curing varnish composition, for example those comprising epoxy resins and UV curable acrylic monomers, or UV polyurethane compositions, since they allow for a fast application and curing cycle. This pigmented layer may comprise a first pigmentation, and a second pigmented layer disposed on the first layer may comprise a second pigmentation different from the first pigmentation.

one or more additional or alternative pigments such as pearlescent pigments, and/or light-interference platelet pigments.

For example, the coloured layer may include one or more colourants such as a pearlescent pigment, a lamellar pigment, a light-interference pigment, and/or a metallic pigment, an encapsulated metallic pigment, a passivated metal pigment, or metallic powder.

Encapsulant

Encapsulant typically are curing or crosslinking polymer systems, usually in the form of a foil, which flows and cured during the lamination process. The front encapsulant layer is typically transparent once cured, whereas the back encapsulant can be transparent, but usually is at least in part pigmented. Preferably, the back encapsulant layer approaches the colour of the PV cells, to form a uniform background with the PV cells after cure.

The polymer materials of the different polymer layers of the present module may vary and largely depend on the desired properties, and functionality. These include ethylene vinyl acetate (EVA), polyvinylbutyral (PVB), polymethylmethacrylate(PMMA), alkylmethacrylate, alkylacrylate copolymers, such as for example polymethacrylate poly-n-butylacrylate (PMMA-PnBA), elastomers, e.g. SEBS, SEPS, SIPS, polyurethanes, polyolefins, functionalized polyolefines, lonomers, thermoplastic polydimethylsiloxane copolymers, or mixtures thereof

Preferably polyvinylbutyral (PVB), silicone, polymethylmethacrylate(PMMA), alkylacrylate copolymers, such as for example polymethacrylate poly-n-butylacrylate (PM MA-PnBA) are used. Other possible polymers are polymethylemethacrylate (PMMA), polyvinylbutyral (PVB), polyvinylidene fluoride (PVDF), polycarbonate (PC), polyurethane, silicone or mixtures thereof.

It should be noted that where a polymer is formulated with a crosslinking mechanism that is initiated above a certain temperature, e.g. ethylenically unsaturated (co)polymers and peroxides, or, the rheology values employed herein refer to materials that are not, or only partially cross-linked.

Once the crosslinking has been complete, e.g. in a photovoltaic module lamination process, the polymers that have cross-linked are no longer considered as thermoplastic materials. Therefore, in so far as the specification refers to photovoltaic modules after lamination, the described properties refer to the polymers prior to the lamination process, also including the cross-linked polymers. The encapsulant layers may be a state-of-the-art encapsulant layer, for example a thermally curable polymer layers such as described herein above.

Suitably the above-described polymer layer comprises of an optionally hydrogenated polystyrene block copolymer with butadiene, isoprene and/or butylenes/ethylene copolymers, for example SIS, SBS and/or SEBS; a polymethacrylate polyacrylate block copolymer, a polyolefin, a polyolefine copolymer or terpolymer, or an olefin copolymer or terpolymer, with copolymerizable functionalised monomers such as methacrylic acid (ionomer). Examples are a poly methyl metacrylate n-butylacrylate block copolymer. A further example comprises a polyolefin, preferably a polyethylene or polypropylene, such as an LDPE type. Polyolefins, such as polyethylene and polypropylene suitable for the inner sub layer include high density polyethylene, medium density polyethylene, low density polyethylene, linear low-density polyethylene, metallocene-derived low density polyethylene, homo-polypropylene, and polypropylene co-polymer.

Preferably, additives may be present in the layers which improve the adhesive strength. In some applications the layers or coatings applied directly onto a glass layer may comprise additives such as silane coupling agents. Both front and back sheet encapsulant, and the entire back-sheet layer may be multi-layered films, typically comprising at least two layers which may be prepared from different polymeric materials.

PV Cells

The photovoltaic cell may be monofacial or bifacial. The photovoltaic cells can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide or CIGS. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Thin-film amorphous silicon materials can also be used, which can be provided in flexible forms. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of encapsulated photovoltaic elements for use in the present invention. In one embodiment of the invention, the encapsulated photovoltaic element includes a monocrystalline silicon photovoltaic cell or a polycrystalline silicon photovoltaic cell. The photovoltaic cells can be interconnected to provide a single set of electrical contacts for a module. The module according to the invention may also be combined with wafer-based photovoltaic cells based on monocrystalline silicon (c-Si), poly- or multi-crystalline silicon (poly-Si or mc-Si) and ribbon silicon. Preferably the module comprising wafer-based PV cells will comprise the top sheet according to the invention as front facing in use the incoming radiation, a polymer layer, a layer comprising a wafer-based PV cell and a back-sheet layer.

The module may be planar or curved, depending on the flexibility and shape of the components, and the desired product aspects. Suitable photovoltaic cells may be crystalline silicon cell, CdTe, aSi, micromorph Si or Tandem junction aSi photovoltaic cells.

In certain embodiments of the invention, the photovoltaic cells, the coloured coating layer, and the encapsulant layer may be provided together as an encapsulated photovoltaic element, which can be affixed to the substrate.

Suitable photovoltaic cells and/or photovoltaic elements can be obtained, for example, from several different suppliers, such as China Electric Equipment Group of Nanjing, Uni-Solar, Sharp, USFC, FirstSolar, General Electric, Schott Solar, Evergreen Solar and Global Solar.

Moreover, the person of skill in the art can fabricate encapsulated photovoltaic elements using techniques such as lamination or autoclave processes. The encapsulated photovoltaic elements can be made, for example, using methods disclosed in U.S. Pat. No. 5,273,608.

The top surface of a photovoltaic cell is the surface presenting its photoelectrically-active areas. When installed, the photovoltaic roofing elements of the present invention should be oriented so that the top surface of the photovoltaic cell(s) is illuminated by solar radiation.

The one or more photovoltaic cells have an operating wavelength range. Solar radiation includes light of wavelengths spanning the near UV, the visible, and the near infrared spectra. As used herein, the term “solar radiation,” when used without further elaboration means radiation in the wavelength range of 300 nm to 1500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of an encapsulated photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the encapsulated photovoltaic element falls within the range of about 300 nm to about 1200 nm. For example, for encapsulated photovoltaic elements having photovoltaic cells based on typical amorphous silicon materials the operating wavelength range is between about 375 nm and about 775 nm; for typical polycrystalline silicon materials the operating wavelength range is between about 600 nm and about 1050 nm; and for typical monocrystalline silicon materials the operating wavelength range is between about 425 nm and about 1175 nm.

Photovoltaic cells themselves also often have a somewhat metallic appearance, and sometimes have a birefringent colour effect also known as “flop,” i.e. depending on the viewing angle and the illumination angle, the observed colour aspect may change.

To achieve better matching of appearance between the photovoltaic elements and the surrounding substrate upon which they are disposed, in certain embodiments of the invention the back encapsulant layer may be, for example, in the main colour tone that approximates the characteristic dark blue colour of a photovoltaic element.

In certain embodiments of the invention, the coloured top sheet may have a metallic or light-interference effect. Such an effect can help impart a metallic visual effect to the module, so as to better mimic the appearance of the photovoltaic cells.

Back Sheet

The backsheet may advantageously comprise a hard polymer, such as for example a layer of PET, metal, a composite material, or preferably a further glass layer. When thin film photovoltaic cells are employed, for example CIGS and CIS type cells, the PV module may advantageously comprise a glass top sheet of the present invention, an encapsulant of the present invention, the thin film photovoltaic cell a second encapsulant layer and a rigid support, such as for example glass.

The back sheet or bottom layer material can be, for example, a fluoropolymer, for example ETFE, PFE, FEP, PVDF or PVF (“TEDLAR”). The bottom layer material may alternatively be, for example, a polymeric material, including polyester such as PET; or a metallic material, such as steel or aluminium sheet, or preferably, a glass sheet.

The back-sheet layer preferably is pigmented, more preferably to resemble the PV cells, or it may comprise a so-called white reflector. The presence of pigments in the backsheet is advantageous because it will reflect radiation to the photovoltaic cell and thus improve the efficiency of the cell. This is in particular beneficial where bifacial PV cells are employed.

Possible backsheet layers comprise fluoropolymer layers. Instead of a fluoropolymer layer a second glass sheet may be provided at the back of the solar cell. This will provide a solar cell which has a glass front and backside. The glass layer for use as backside will preferably have a thickness of less than 3 mm.

The glass layers may be as described above. The use of a glass front and backside is advantageous because it provides a structural strength to the panel such that no aluminium frame is necessary. The glass backside will also provide an absolute barrier towards water ingress and the like which is advantageous for extending the life time of the panel. The use of the glass layer will make it possible to avoid the use of a back sheet comprising a fluoropolymer.

Modules

One or more of the photovoltaic elements described herein above may be combined to a larger element for installation as part of a photovoltaic system for the generation of electric power.

Accordingly, one embodiment of the invention is a photovoltaic architectural system disposed on a building, noise barrier wall, roof deck or the like, comprising one or more photovoltaic roofing elements as described above disposed thereon. The photovoltaic module may comprise cells that are monofacial or bifacial, or both.

The photovoltaic elements of the photovoltaic roofing elements are desirably connected to an electrical system, either in series, in parallel, or in series-parallel, as would be recognized by the skilled artisan. There can be one or more layers of material, such as underlayment, between the roof deck and the photovoltaic roofing elements of the present invention.

The photovoltaic roofing elements of the present invention can be installed on an existing building or roof; in such embodiments, there may be one or more layers of “dummy” i.e., non-photovoltaic cladding elements that have the same built-up, but are void of photovoltaic cells, but provide essentially the same optical effect and protection from the environment, and the photovoltaic elements according to the present invention.

Photovoltaic elements of the present invention can be fabricated using many techniques familiar to the skilled artisan. It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

1. A photovoltaic element comprising:
i. a light transmissive, coloured multilayer top sheet having an appearance that exhibits a colouration change depending on the viewing angle, the top sheet comprising:
a. a textured transparent front cover sheet, and
b. a pigmented top coating layer disposed on the backside of the top sheet with respect to the direction of the incandescent light;
ii. a first encapsulant layer;
iii. one or more photovoltaic cells, each comprising at least one photovoltaically active surface, and comprising two electrically conductive electrode layers with a photovoltaic material disposed between them;
iv. a second encapsulant layer, and
v. a back cover sheet.

2. The photovoltaic element according to claim 1, wherein the top sheet is birefringent.

3. The photovoltaic element according to claim 1 or claim 2, wherein the pigmented coating ii.) comprises effect pigments exhibiting a colour flop; preferably, pearlescent pigments, nacreous pigments, metal flake pigments and/or an encapsulated metal flake pigments.

4. The photovoltaic element according to any one of claims 1 to 3, wherein the one or more photovoltaic cells comprise two photovoltaically active surfaces.

5. The photovoltaic element according to any one of claims 1 to 4, wherein the top coating layer further comprises infrared reflective pigments, to lower the module temperature during use.

6. The photovoltaic element according to any one of claims 1 to 5, wherein the top coating layer comprises a crosslinked polymeric binder composition, and optionally, UV- and acid stabilizers.

7. The photovoltaic element according to claim 6, wherein the crosslinked binder polymeric composition comprises at least a rigid polymeric resin components and a crosslinked component.

8. The photovoltaic element according to claim 6 or claim 7, wherein the crosslinked component is derived from a radiation curable composition.

9. The photovoltaic element according to any one of claims 6 to 8, wherein the crosslinked polymeric binder composition comprises one or more epoxy resins, polycarbonates, polystyrenes, polyurethanes, polyacrylates and/or polymethacrylates.

10. The photovoltaic element according to any one of the preceding claims, wherein the textured top sheet a) comprises a textured glass substrate.

11. The photovoltaic element according to claim 10, wherein the top sheet comprises tempered glass sheet having a texture applied thereto at least on one side, and optionally an anti-reflective coating.

12. The photovoltaic element according to claim 10 or 11, wherein the top sheet has a thickness of from 1 to 5 mm, preferably of from 2 to 4 mm.

13. A method of preparing a photovoltaic element according to any one of the preceding claims, comprising:
a) coating a textured transparent front cover sheet with a pigmented coating composition in suitable thickness comprising one or more of a pearlescent pigment, a nacreous pigment, a metal flake pigment and/or an encapsulated metal flake pigment composition, and
b) subjecting the coated top sheet to a curing process, to obtain the textured coloured light transmissive birefringent multilayer front cover sheet having an appearance that exhibits a colouration change depending on the viewing angle.

14. A method according to claim 13, wherein the coating process is wet coating process, and wherein the curing process is a radiation curing process.

15. A method according to claim 13 or 14, further comprising
c) providing a stack comprising the light transmissive coloured top sheet obtained according to claim 13 or 14, a first encapsulant material, one or more photovoltaic cells comprising at least one photovoltaically active surface and comprising two electrically conductive electrode layers with a photovoltaic material disposed between them, a second encapsulant material, and
d) subjecting the stack obtained in c) to a suitable pressure and temperature, to obtain a photovoltaic element.

16. A photovoltaic element comprising a plurality of photovoltaic elements according to any one of claims 1 to 11, or obtainable according to the method of claims 12 to 15, for disposition on a structure.

17. A panel complementary to the elements according to any one of claims 1 to 12, comprising
i. a coloured, light transmissive birefringent multilayer top sheet having an appearance that exhibits a colouration change depending on the viewing angle, the sheet comprising
a. a textured transparent front cover sheet, and
b. a pigmented top coating layer disposed on the inside of the top sheet with respect to the direction of the incandescent light;
ii. a first encapsulant layer,
iii. a second encapsulant layer, and
iv. a back cover sheet.
